(19) United States
(12) Patent Application Publication
(10) Pub. No.: US 2008/0158826 A1
(43) Pub. Date: Jul. 3, 2008

(54) Composite module

(75) Inventors: Mikine Fujihara, Fukaya-shi (JP); Masahiro Kobayashi, Kazo-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/976,152

(22) Filed: Oct. 22, 2007

(30) Foreign Application Priority Data
Dec. 27, 2006 (JP) 2006-353299

(51) Int. Cl. H05K 7/20

(52) U.S. Cl. 361/716

(57) ABSTRACT

According to one embodiment, a composite module includes a substrate, a first module mounted on the substrate, a second module mounted on the substrate and provided to be independent from the first module, and a heat radiating plate. The heat radiating plate is thermally connected to each of the first module and the second module, and serves to radiate heat from these modules to an outside.

### CROSS-REFERENCE TO RELATED APPLICATIONS

This application is based upon and claims the benefit of priority from Japanese Patent Application No. 2006-353299, filed Dec. 27, 2006, the entire contents of which are incorporated herein by reference.

### BACKGROUND

1. Field

One embodiment of the invention relates to a composite module including a plurality of modules.

2. Description of the Related Art

For example, Jpn. Pat. Appln. KOKAI Publication No. 2006-278395 discloses a data processing terminal of the following structure. That is, the data processing terminal includes a CPU, an UBS controller, a substrate on which these members are mounted, a first heat conductive plate that cools down the CPU, a second heat conductive plate that cools down the USB controller, a wavy shaped plate that connects the first heat conductive plate and the a second heat conductive plate to each other, and a third heat conductive plate to which heat of the first and second heat conductive plates is transmitted. The plate is made of a metal having a sufficiently low heat conductivity.

In the data processing terminal, the heat generated by the CPU is transmitted to the third heat conductive plate via the first heat conductive plate. The heat generated by the USB controller is transmitted to the third heat conductive plate via the second heat conductive plate. However, here, the plate serves to inhibit the heat generated by the CPU from being transmitted to the USB controller and also inhibit the heat generated by the USB controller from being transmitted to the CPU. Thus, with the structure that the pathway of the heat conduction is divided as described above, efficient heat radiation can be achieved.

However, in the above-described conventional data processing terminal, there may be such a case where the amount of heat generation differs between the CPU and USB controller depending on the contents of the process. More specifically, when such a process that uses the CPU only is repeatedly carried out, it is likely that the temperature of the CPU only increases, causing an uneven temperature distribution on the substrate. In this case, the temperature of the vicinity of the CPU increases in the data processing terminal to such a level that it cannot be sufficiently cooled down, possibly causing an adverse effect on other parts in the data processing terminal.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view showing a portable computer, which is an example of electronic device according to the first embodiment;

FIG. 2 is an exemplary perspective view showing a composite module housed in a housing of the portable computer shown in FIG. 1;

FIG. 3 is an exemplary decomposed perspective view showing the composite module shown in FIG. 2;

FIG. 4 is an exemplary cross sectional view showing the composite module shown in FIG. 2 taken in its longitudinal direction;

FIG. 5 is an exemplary perspective view showing a composite module according to the second embodiment;

FIG. 6 is an exemplary decomposed perspective view showing the composite module shown in FIG. 5;

FIG. 7 is an exemplary cross sectional view showing the composite module shown in FIG. 5 taken in its longitudinal direction;

FIG. 8 is an exemplary perspective view showing a composite module according to the third embodiment;

FIG. 9 is an exemplary decomposed perspective view showing the composite module shown in FIG. 8; and

FIG. 10 is an exemplary cross sectional view showing the composite module shown in FIG. 8 taken in its longitudinal direction.

### DETAILED DESCRIPTION

Various embodiments according to the invention will be described hereinafter with reference to the accompanying drawings. In general, according to one embodiment of the invention, a composite module includes a substrate, a first module mounted on the substrate, a second module mounted on the substrate and provided to be independent from the first module, and a heat radiating plate. The heat radiating plate is thermally connected to each of the first module and the second module, and serves to radiate heat from these modules to an outside.

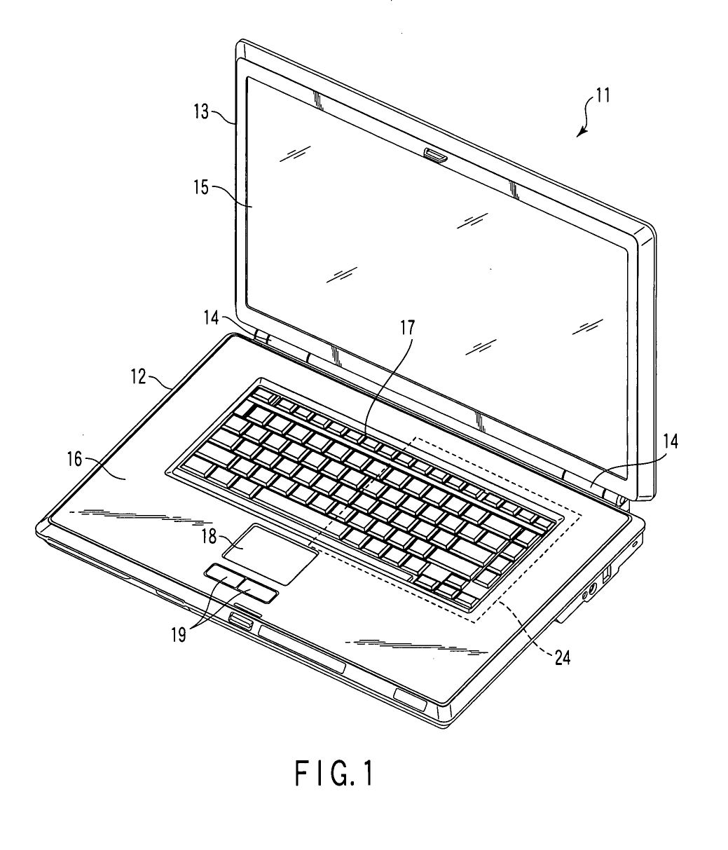

Embodiments of the electronic device will now be described with reference to FIGS. 1 to 4. As shown in FIG. 1, a portable computer 11, which is an example of the electronic device, includes a main body unit 12, a display unit 13, and a hinge mechanism 14 provided between the main body unit 12 and display unit 13. The hinge mechanism 14 supports the display unit 13. With the hinge mechanism 14, the display unit 13 can be pivoted with respect to the main body unit 12.

The display unit 13 includes a liquid crystal display 15. The liquid crystal display 15 is an example of the display device connected to a main substrate contained in the main body to display data. It should be noted here that the display mounted on the display unit 13 is not limited to the liquid crystal display 15, but, alternatively, it may be a plasma display, an organic electro-luminescence type display, a surface-conduction electron-emitter display or the like.

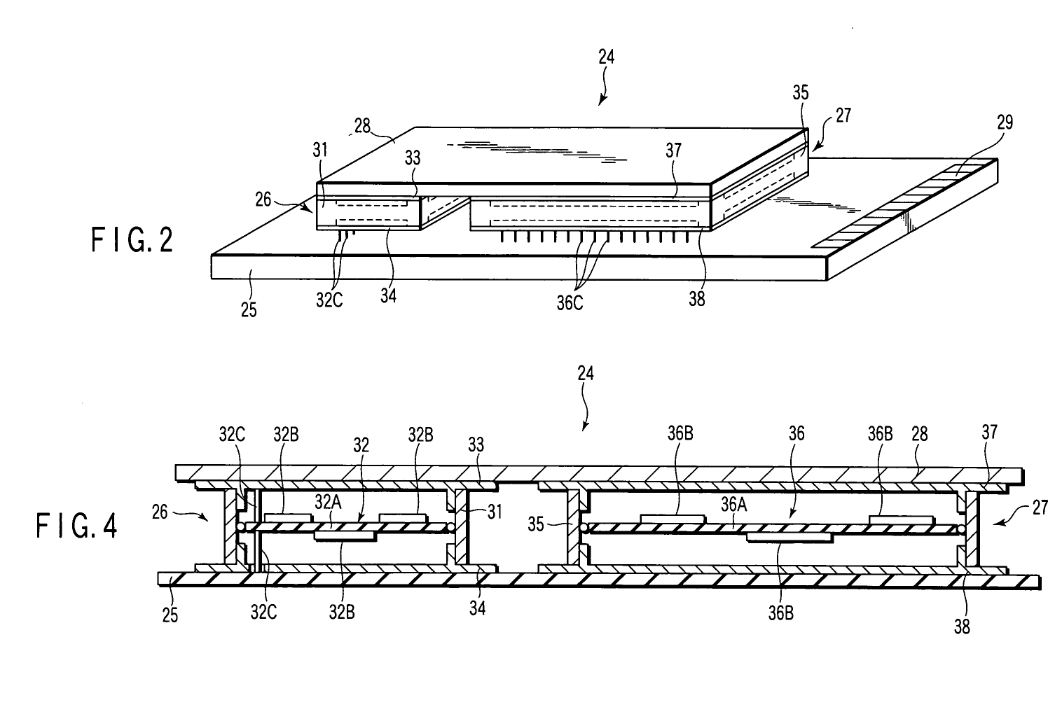

The main body unit 12 includes a housing 16, a keyboard 17, and a touch pad 18 and buttons 19, which, in combination, function as a pointing device. As shown in FIG. 2, the main body unit 12 houses, inside the housing 16, a main substrate (not shown in the figure), a composite module 24 and a fan (not shown) that cools the composite module 24. The main substrate is a circuit board on which main circuit components such as CPU and graphics chips are mounted. The main substrate and composite module 24 are electrically connected to each other via, for example, a connector.

As shown in FIG. 2, the composite module 24 includes a substrate 25, a first module 26 mounted on the substrate 25, a second module 27 mounted on the substrate 25 but to be independent from the first module 26, and a heat radiating plate 28 thermally connected to each of the first module 26 and the second module 27. The substrate 25 is a printed wiring board and it includes a connector portion 29 that electrically connects itself to, for example, the main substrate. The heat radiating plate 28 is a single aluminum plate having a rectangular shape. The heat radiating plate 28 is able to radiate the heat of the first module 26 and the second module 27 to the outside. The heat radiating plate 28 is arranged to overly on both of the first module 26 and the second module 27.

The first module 26 is an analog television tuner. The first module 26 includes a first frame body 31, a first printed circuit board 32 housed inside the first frame body 31, a first cover 33 mounted on an upper side of the first frame body 31 and a second cover 34 mounted on an lower side of the first frame body 31. The first printed circuit board 32 includes a first substrate main body 32A, a plurality of circuit components 32B mounted on the first substrate main body 32A and terminals 32C extending from the first substrate main body 32A. The first printed circuit board 32 is fixed to, for example, the first frame body 31 by soldering. The first frame body 31, the first cover 33 and the second cover 34 are each made of a metal material.

The second module 27 is a digital television tuner. The second module 27 includes a second frame body 35, a second printed circuit board 36 housed inside the second frame body 35, a third cover 37 mounted on an upper side of the second frame body 35 and a fourth cover 38 mounted on an lower side of the second frame body 35. The second printed circuit board 36 includes a second substrate main body 36A, a plurality of circuit components 36B mounted on the second substrate main body 36A and terminals 36C extending from the second substrate main body 36A. The second printed circuit board 36 is fixed to, for example, the second frame body 35 by soldering. The second frame body 35, the third cover 37 and the fourth cover 38 are each made of a metal material. Since the first module 26 is an analog television tuner, the amount of heat generated from the first module 26 is larger than the second module 27, which is a digital television tuner. Further, the area of the second module 27 is larger than that of the first module 26.

The cooling operation of the composite module 24 of the portable computer 11 will now be described with reference to FIG. 4. In order to receive an analog-mode television signal, the first module 26 is used, and when it is received, the temperature of the first printed circuit board 32 of the first module 26 increases. Therefore, the heat of the first module 26 is transmitted to the heat radiating plate 28, thereby cooling the first module 26. During this period, the second module 27 is not used, and there is a temperature gradient created between the first module 26 and the second module 27. Due to the gradient, the heat of the first module 26 is transmitted to the second module 27 via the heat radiating plate 28. In other words, the first module 26 is cooled down by diffusing the heat of the first module 26 to the heat radiating plate 28 and the second module 27, which is not in operation.

Similarly, in the portable computer 11, the second module 27 is used to receive a digital-mode television signal, and when it is received, the temperature of the second printed circuit board 36 of the second module 27 increases. Therefore, the heat of the second module 27 is transmitted to the heat radiating plate 28, thereby cooling the second module 27. During this period, the first module 26 is not used, and there is a temperature gradient created between the second module 27 and the first module 26. Due to the gradient, the heat of the second module 27 is transmitted to the first module 26 via the heat radiating plate 28. In other words, the second module 27 is cooled down by diffusing the heat of the second module 27 to the heat radiating plate 28 and the first module 26, which is not in operation.

In the meantime, when a television program is received in the analog mode signal and the received program is recorded in the digital mode, both of the first module 26 and the second module 27 are used. In this case, the amount of heat generated from the first module 26, which is the analog television tuner is larger than the amount of heat generated from the second module 27, which is the digital television module. Therefore, there is a temperature gradient created between the second module 27 and the first module 26. Then, the heat of the first module 26 is transmitted to the heat radiating plate 28 and the second module 27, thereby equalizing the temperature of the first module 26 and that of the second module 27 to each other. Then, the heat of the first module 26 and that of the second module 27 are radiated to the outside via the heat radiating plate 28. Note that the heat of the heat radiating plate 28 is radiated out to the outside of the housing 16 actively via the fan.

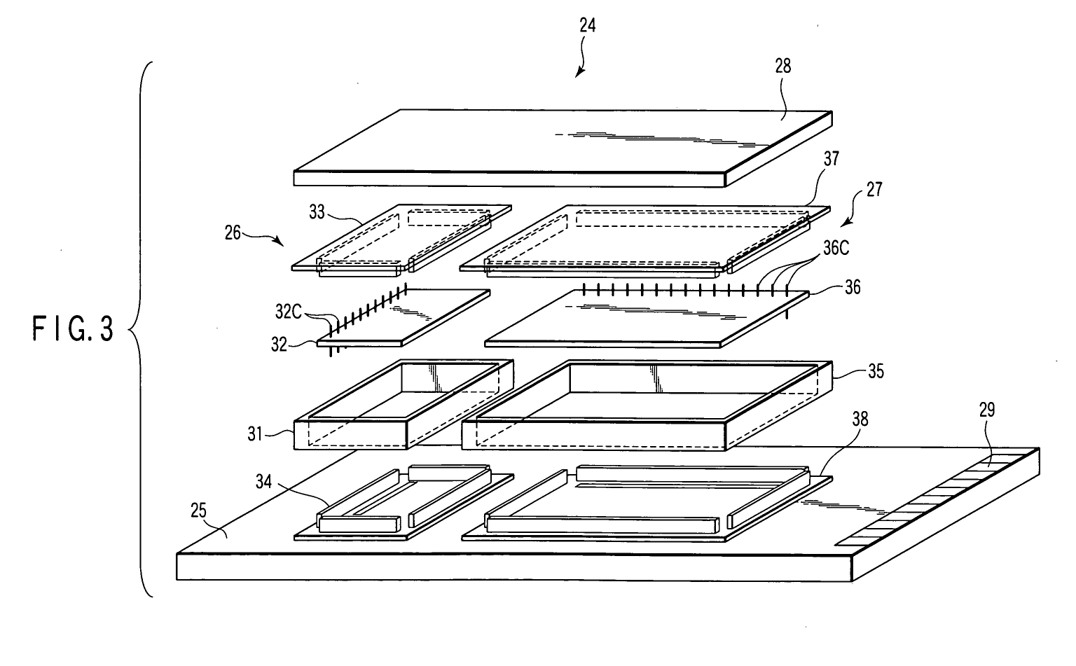

Next, the assembly step for the composite module 24 of this embodiment will now be described with reference to FIG. 3. First, the second cover 34 and the fourth cover 38 are mounted to the substrate 25. The first frame body 31 is mounted to the upper side of the second cover 34. The second frame body 35 is mounted to the upper side of the fourth cover 38. The first printed circuit board 32 is fixed to the first frame body 31 by soldering. The second printed circuit board 36 is fixed to the second frame body 35 by soldering.

Meanwhile, the first cover 33 and the second cover 34 are secured to the heat radiating plate 28 by, for example, calking in advance. Then, the heat radiating plate 28 is mounted to the substrate 25 in such a matter that the first cover 33 on the heat radiating plate 28 is aligned with the first frame body 31 and the second cover 34 is aligned with the second frame body 35. Thus, the setting of the first cover 33 to the first frame 31 and the setting of the second cover 34 to the second frame body 35 are carried out at once, and the assembling of the composite module 24 is completed.

Up to here, the first embodiment of the portable computer 11 has been described. According to this embodiment, the composite module 24 is thermally connected to both of the first module 26 and the second module 27, and it includes the heat radiating plate 28 that radiates the heat of these to the outside. With this structure, the heat radiating plate 28 serves to radiate the heat of the first module 26 and that of the second module 27, and also to thermally connect the first module 26 and the second module 27 to each other. Therefore, for example, when the first module 26 is generating heat, the heat is released to the heat radiating plate 28 and the second module 27 to equalize the temperatures of the modules. Thus, the first module 26 is cooled down. On the other hand, when the second module 27 is generating heat, the heat is released to the heat radiating plate 28 and the first module 26 to equalize the temperatures of the modules. Thus, the second module 27 is cooled down.

In this case, the heat radiating plate 28 is placed to overly on both of the first module 26 and the second module 27. With this structure, the space for placing the heat radiating plate 28 can be made small, and the efficiency of usage of the space within the housing 16 of the portable computer 11 can be improved.

Here, the amount of heat generated from the first module 26 is larger than that of the second module 27. Therefore, when both of the first module 26 and the second module 27 are used at the same time, there is a temperature gradient created between the first module 26 and the second module 27. Due to the temperature gradient, the heat generated from the first module 26 can be diffused to the second module 27 via the heat radiating plate 28. In this manner, the temperature is made even between both of the modules 26 and 27, and as a result, the first module 26 can be cooled down.

Further, here, the area of the second module 27 is larger than the area of the first module 26. With this structure, the second module 27 which is larger in area can also serve as an efficient heat radiating mechanism for the first module 26 that has a larger amount of heat generation. Thus, it becomes no longer necessary to provide a separate heat radiating mechanism for the first module 26, and thus the number of parts and the space occupied by the composite module 24 can be reduced.

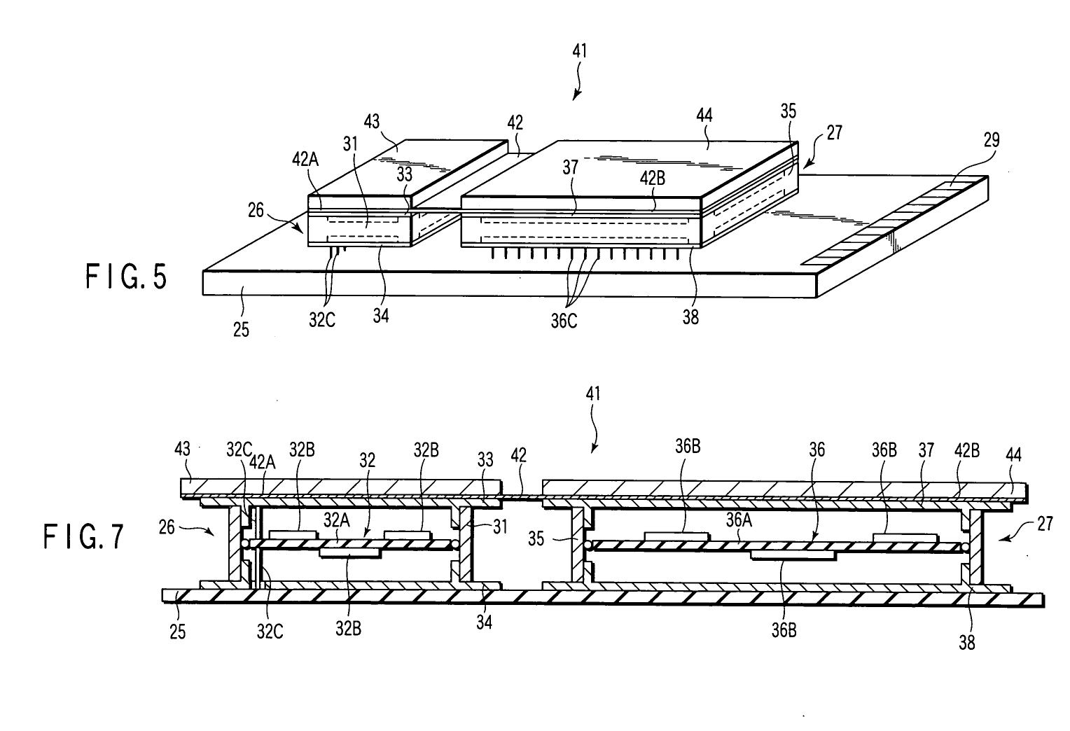

The second embodiment of a composite module 41 used in the portable computer 11 will now be described with reference to FIGS. 5 to 7. The composite module 41 of the second embodiment is different from that of the first embodiment in the respect of whether the structure of the heat radiating plate and a heat conducting sheet 42 are present or absent, but the rest of the structure is similar to that of the first embodiment. Therefore, the different part will be discussed mainly. The common parts will be designated by the same reference numerals, and the explanations therefor will not be repeated.

As shown in FIG. 5, the composite module 41 of the second embodiment includes a substrate 25, a first module 26 mounted on the substrate 25, a second module 27 mounted on the substrate 25 such as to be independent from the first module 26, a heat conductive sheet 42 that thermally connects the first module 26 and the second module 27 to each other, a first heat radiating plate 43 fixed to an upper side of the heat conductive sheet 42 such as to be overlaid on the first module 26, and a second heat radiating plate 44 fixed to an upper side of the heat conductive sheet 42 such as to be overlaid on the second module 27.

The heat conductive sheet 42 is made of, for example, a carbon graphite sheet and has a high thermal conductivity. The heat conductive sheet 42 includes a first end portion 42A overlaid on the first module 26 and a second end portion 42B overlaid on the second module 27. The heat conductive sheet 42 is able to thermally connect the first module 26 and the second module 27 to each other. The material for the heat conductive sheet 42 is not limited to the carbon graphite sheet, but it may be alternative a copper foil.

The first heat radiating plate 43 is an aluminum plate of a square shape, and the second heat radiating plate 44 is an aluminum plate of a rectangular shape. The first heat radiating plate 43 is placed on an opposite side to the first module 26 with regard to the first end portion 42A. In other words, the first end portion 42A of the heat conductive sheet 42 is interposed between the first heat radiating plate 43 and the first module 26.

The second heat radiating plate 44 is provided to be independent from the first heat radiating plate 43. The second heat radiating plate 44 is placed on an opposite side to the second module 27 with regard to the second end portion 42B. In other words, the second end portion 42B of the heat conductive sheet 42 is interposed between the second heat radiating plate 44 and the second module 27. The first heat radiating plate 43 and the second heat radiating plate 44 can radiate the eat of the heat conductive sheet 42 to the outside.

Next, the cooling operation of the composite module 41 will now be described with reference to FIG. 7. In order for the portable computer 11 to receive an analog-mode television signal, the first module 26 is used, and when it is received, the temperature of the first printed circuit board 32 of the first module 26 increases. Therefore, the heat of the first module 26 is transmitted to the heat conductive sheet 42, thereby cooling the first module 26. During this period, the second module 27 is not used, and there is a temperature gradient created between the first module 26 and the second module 27. Due to the gradient, the heat of the first module 26 is transmitted to the second module 27 via the heat conductive sheet 42. In other words, the first module 26 is cooled down by diffusing the heat of the first module 26 to the first and second heat radiating plates 43 and 44 and the second module 27, which is not in operation.

Similarly, in the portable computer 11, the second module 27 is used to receive a digital-mode television signal, and when it is received, the temperature of the second module 27 increases. Therefore, the heat of the second module 27 is transmitted to the heat conductive sheet 42, thereby cooling the second module 27. During this period, the first module 26 is not used, and there is a temperature gradient created between the second module 27 and the first module 26. Due to the gradient, the heat of the second module 27 is transmitted to the first module 26 via the heat conductive sheet 42. In other words, the second module 27 is cooled down by diffusing the heat of the second module 27 to the first and second heat radiating plates 43 and 44 and the first module 26, which is not in operation.

In the meantime, when a television program is received in the analog mode signal and the received program is recorded in the digital mode, both of the first module 26 and the second module 27 are used. In this case, the amount of heat generated from the first module 26, which is the analog television tuner, is larger than the amount of heat generated from the second module 27, which is the digital television module. Therefore, there is a temperature gradient created between the second module 27 and the first module 26. Then, the heat generated from the first module 26 is transmitted to the first and second heat radiating plates 43 and 44 and the second module 27, thereby equalizing the temperature of the first module 26 and that of the second module 27 to each other. Then, the heat of the first module 26 and that of the second module 27 are radiated to the outside via the first and second heat radiating plates 43 and 44. Note that the heat of the first and second heat radiating plates 43 and 44 is radiated out to the outside of the housing 16 actively via the fan.

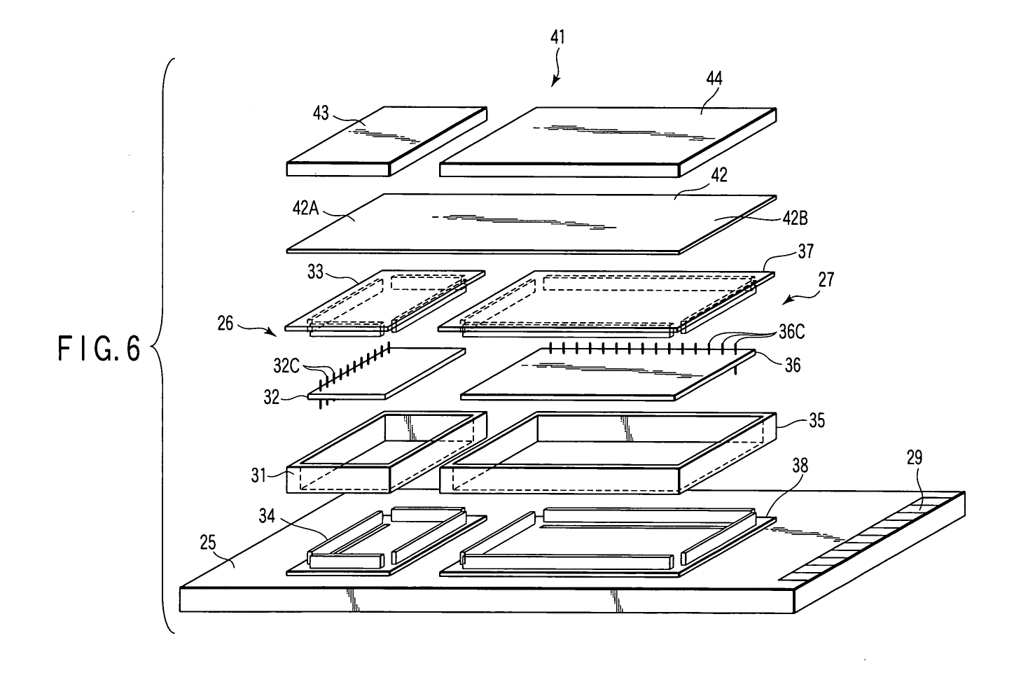

Next, the assembly step for the composite module 41 of this embodiment will now be described with reference to FIG. 6. First, the second cover 34 and the fourth cover 38 are mounted to the substrate 25. The first frame body 31 is mounted to the upper side of the second cover 34. The second frame body 35 is mounted to the upper side of the fourth cover 38. The first printed circuit board 32 is fixed to the first frame body 31 by soldering. The second printed circuit board 36 is fixed to the second frame body 35 by soldering.

Meanwhile, the first cover 33 is secured to the first heat radiating plate 43 by, for example, calking in advance. The second cover 34 is secured to the first heat radiating plate 44 by, for example, calking in advance. Then, the first end portion 42A of the heat conductive sheet 42 is arranged on the upper side of the first frame body 31, and the first cover 33, which is integrated with the first heat radiating plate 43, is mounted on the first frame body 31. In this manner, the first end portion 42A of the heat conductive sheet 42 is interposed between the first frame body 31 and the first cover 33. Further, the second end portion 42B of the heat conductive sheet 42 is arranged on the upper side of the second frame body 35, and the second cover 34, which is integrated with the second heat radiating plate 44, is mounted on the second frame body 35. In this manner, the second end portion 42B of the heat conductive sheet 42 is interposed between the second frame body 35 and the second cover 34. Thus, the assembly of the composite module 41 is completed.

Up to here, the second embodiment of the composite module 41 has been described. According to this embodiment, the composite module 41 includes the first module 26, the second module 27, the heat conductive sheet 42, the first heat radiating plate 43 arranged to interpose the first end portion 42A of the heat conductive sheet 42 between itself and the first module 26, and the second heat radiating plate 44 provided to be independent from the first heat radiating plate 43 and arranged to interpose the second end portion 42B of the heat conductive sheet 42 between itself and the second module 27.

With this structure, the heat of the first module 26 and that of the second module 27 can be radiated via the first heat radiating plate 43 and the second heat radiating plate 44, respectively. Further, the heat conductive sheet 42 serves to thermally connect the first module 26 and the second module 27 to each other. Therefore, for example, when the first module 26 is generating heat, the heat is released to the first and second heat radiating plates 43 and 44 and the second module 27 to equalize the temperatures of the modules. Thus, the first module 26 can be cooled down. On the other hand, when the second module 27 is generating heat, the heat is released to the first and second heat radiating plate 43 and 44 and the first module 26 to equalize the temperatures of the modules. Thus, the second module 27 can be cooled down.

With the technique of the first embodiment, in case where there is a variation between the first module 26 and the second module 27 in height when they are actually manufactured, such a problem might occur that the heat radiating plate 28 can be brought into contact with the first module 26, whereas the heat radiating plate 28 cannot be brought into contact with the second module 27. Here, with the second embodiment, even if there is a variation between the first module 26 and the second module 27 in height when they are actually manufactured, the first heat radiating plate 43 can be brought into contact with the first module 26, and also the second heat radiating plate 44 can be brought into contact with the second module 27.

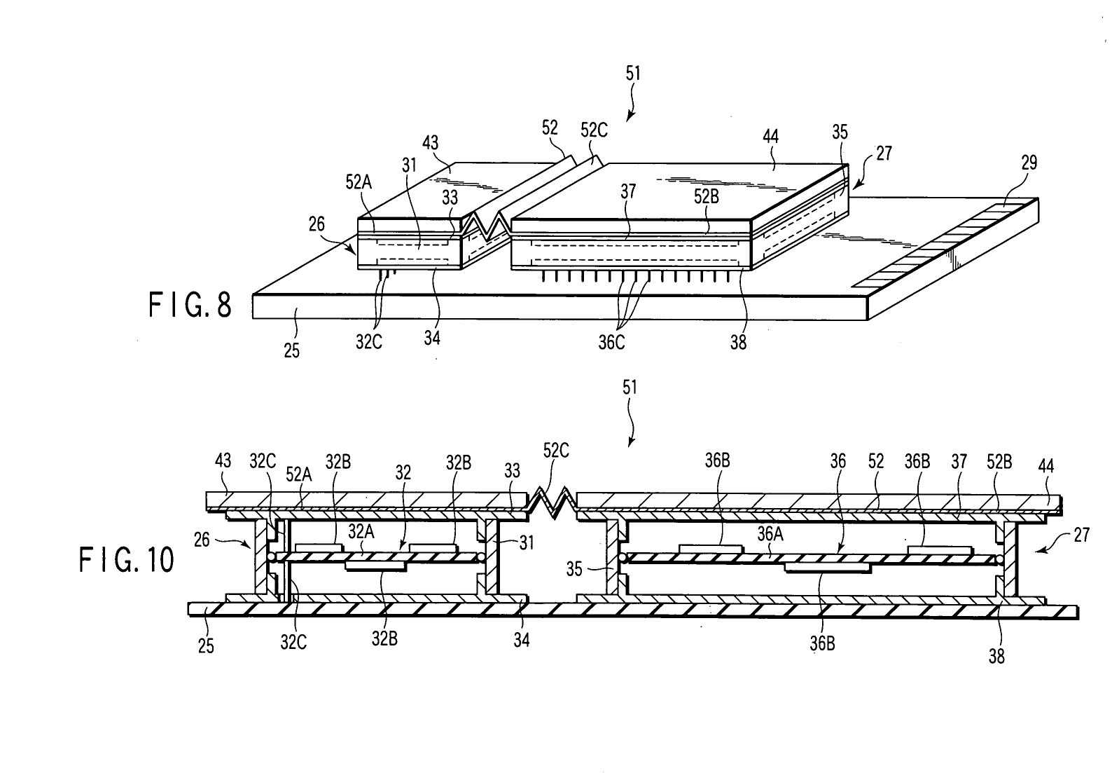

The third embodiment of a composite module 51 used in the portable computer 11 will now be described with reference to FIGS. 8 to 10. The composite module 51 of the third embodiment is different from that of the first embodiment in the respect of the structure of a heat conducting sheet 52, but the rest of the structure is similar to that of the second embodiment. Therefore, the different part will be discussed mainly. The common parts will be designated by the same reference numerals, and the explanations therefor will not be repeated.

As shown in FIG. 5, the composite module 51 of the third embodiment includes a substrate 25, a first module 26 mounted on the substrate 25, a second module 27 mounted on the substrate 25 such as to be independent from the first module 26, a heat conductive sheet 52 that thermally connects the first module 26 and the second module 27 to each other, a first heat radiating plate 43 fixed to an upper side of the heat conductive sheet 52 such as to be overlaid on the first module 26, and a second heat radiating plate 44 fixed to an upper side of the heat conductive sheet 52 such as to be overlaid on the second module 27.

The heat conductive sheet 52 is made of, for example, a copper foil and has a high thermal conductivity and a high electro-conductivity. The heat conductive sheet 52 includes a first end portion 52A overlaid on the first module 26, a second end portion 52B overlaid on the second module 27, and an intermediate portion 52C having a shape of bellows. The heat conductive sheet 52 is able to thermally connect the first module 26 and the second module 27 to each other. The material for the heat conductive sheet 52 is not limited to the copper foil, but it may be alternative a carbon graphite sheet.

Next, the cooling operation of the composite module 51 will now be described with reference to FIG. 10. In order for the portable computer 11 to receive an analog-mode television signal, the first module 26 is used, and when it is received, the temperature of the first module 26 increases. During this period, the second module 27 is not used, and there is a temperature gradient created between the first module 26 and the second module 27. Due to the gradient, the heat of the first module 26 is transmitted to the first and second heat radiating plates 43 and 44 and the second module 27, which is not in operation. Thus, the first module 26 is cooled down.

Similarly, in the portable computer 11, the second module 27 is used to receive a digital-mode television signal, and when it is received, the temperature of the second module 27 increases. During this period, the first module 26 is not used, and there is a temperature gradient created between the second module 27 and the first module 26. Due to the gradient, the heat of the second module 27 is transmitted to the first and second heat radiating plates 43 and 44 and the first module 26, which is not in operation. Thus, the second module 27 is cooled down.

In the meantime, when a television program is received in the analog mode signal and the received program is recorded in the digital mode, both of the first module 26 and the second module 27 are used. In this case, the amount of heat generated from the first module 26, which is the analog television tuner, is larger than the amount of heat generated from the second module 27, which is the digital television module. Therefore, there is a temperature gradient created between the second module 27 and the first module 26. Then, the heat generated from the first module 26 is transmitted to the first and second heat radiating plates 43 and 44 and the second module 27, thereby equalizing the temperature of the first module 26 and that of the second module 27 to each other. Then, the heat of the first module 26 and that of the second module 27 are radiated to the outside via the first and second heat radiating plates 43 and 44. Note that the heat of the first and second heat radiating plates 43 and 44 is radiated out to the outside of the housing 16 actively via the fan.

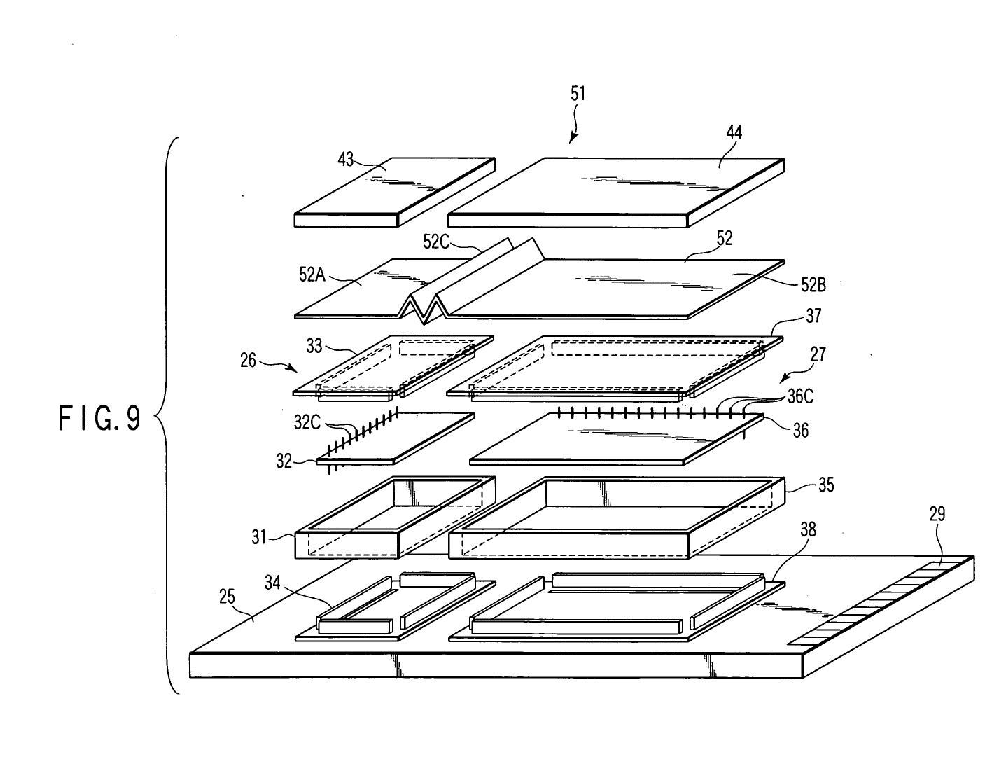

Next, the assembly step for the composite module 51 of this embodiment will now be described with reference to FIG. 9. First, the second cover 34 and the fourth cover 38 are mounted to the substrate 25. The first frame body 31 is mounted to the upper side of the second cover 34. The second frame body 35 is mounted to the upper side of the fourth cover 38. The first printed circuit board 32 is fixed to the first frame body 31 by soldering. The second printed circuit board 36 is fixed to the second frame body 35 by soldering.

Meanwhile, the first cover 33 is secured to the first heat radiating plate 43 by, for example, calking in advance. The second cover 34 is secured to the first heat radiating plate 44 by, for example, calking in advance. Then, the first end portion 52A of the heat conductive sheet 52 is arranged on the upper side of the first frame body 31, and the first cover 33, which is integrated with the first heat radiating plate 43, is mounted on the first frame body 31. In this manner, the first end portion 52A of the heat conductive sheet 52 is interposed between the first frame body 31 and the first cover 33. Further, the second end portion 52B of the heat conductive sheet 52 is arranged on the upper side of the second frame body 35, and the second cover 34, which is integrated with the second heat radiating plate 44, is mounted on the second frame body 35. In this manner, the second end portion 52B of the heat conductive sheet 52 is interposed between the second frame body 35 and the second cover 34. Thus, the assembly of the composite module 51 is completed.

Up to here, the third embodiment of the composite module 51 has been described. According to this embodiment, the composite module 51 includes the first module 26, the second module 27, the heat conductive sheet 52 which has the intermediate portion 52C of a shape of bellows, the first heat radiating plate 43 arranged to interpose the first end portion 52A of the heat conductive sheet 52 between itself and the first module 26, and the second heat radiating plate 44 provided to be independent from the first heat radiating plate 43 and arranged to interpose the second end portion 52B of the heat conductive sheet 52 between itself and the second module 27.

With this structure, the heat of the first module 26 and that of the second module 27 can be radiated via the first heat radiating plate 43 and the second heat radiating plate 44, respectively. Further, the heat conductive sheet 52 serves to thermally connect the first module 26 and the second module 27 to each other.

Therefore, for example, when the first module 26 is generating heat, the heat is released to the first and second heat radiating plates 43 and 44 and the second module 27 to equalize the temperatures of the modules. Thus, the first module 26 can be cooled down. On the other hand, when the second module 27 is generating heat, the heat is released to the first and second heat radiating plate 43 and 44 and the first module 26 to equalize the temperatures of the modules. Thus, the second module 27 can be cooled down.

With the technique of the first embodiment, in case where there is a variation between the first module 26 and the second module 27 in height when they are actually manufactured, such a problem might occur that the heat radiating plate 28 can be brought into contact with the first module 26, whereas the heat radiating plate 28 cannot be brought into contact with the second module 27. Here, with the third embodiment, even if there is a variation between the first module 26 and the second module 27 in height when they are actually manufactured, the first heat radiating plate 43 can be brought into contact with the first module 26, and also the second heat radiating plate 44 can be brought into contact with the second module 27. Especially, as compared to the second embodiment, the composite module 51 of the third embodiment has the heat conductive sheet 52 with the intermediate portion 52C having a shape of bellows, and with this structure, the degree of freedom of the layout is improved. Therefore, even if there is a variation between the first module 26 and the second module 27 in height, such an error can be smoothly taken care of.

Further, the heat conductive sheet 52 has an electro-conductivity. With this structure, the impedance between the first module 26 and the second module 27 can be reduced, and thus the irradiation of electromagnetic wave between these can be prevented.

The electronic device of the present invention is not limited to portable computers, but it is applicable to some other electronic device such as a mobile information terminal. Further, the electronic device can be modified into various versions as long as the essence of the technology does not fall out of the scope of the invention.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A composite module comprising:
a substrate;
a first module mounted on the substrate;
a second module mounted on the substrate and provided to be independent from the first module; and
a heat radiating plate thermally connected to each of the first module and the second module, which radiates heat from these modules to an outside.

2. The composite module according to claim 1, wherein the heat radiating plate is arranged to be overlaid on both of the first module and the second module.

3. The composite module according to claim 2, wherein an amount of heat generated from the first module is larger than that of the second module.

4. The composite module according to claim 3, wherein an area of the second module is larger than that of the first module.

5. A composite module comprising:
a substrate;
a first module mounted on the substrate;
a second module mounted on the substrate and provided to be independent from the first module;
a heat conductive sheet including a first end portion overlying on the first module and a second end portion overlying on the second module, and thermally connecting the first module and the second module to each other;
a first heat radiating plate placed on an opposite side to the first module while interposing the first end therebetween, which radiates heat of the heat conductive sheet to an outside; and
a second heat radiating plate provided to be independent from the first heat radiating plate and placed on an opposite side to the second module while interposing the second end therebetween, which radiates heat of the heat conductive sheet to the outside.

6. The composite module according to claim 5, wherein the heat conductive sheet includes an intermediate portion having a shape of bellows.

7. The composite module according to claim 5, wherein the heat conductive sheet has an electro-conductivity.

8. The composite module according to claim 5, wherein an amount of heat generated from the first module is larger than that of the second module.

9. The composite module according to claim 8, wherein an area of the second module is larger than that of the first module.
